(19) United States
(12) Patent Application Publication
(10) Pub. No.: US 2013/0229161 A1
(43) Pub. Date: Sep. 5, 2013

(54) MODULATING DETERMINATION APPARATUS, MODULATING DETERMINATION METHOD, AND POWER SUPPLY CIRCUIT THEREOF

(71) Applicant: REALTEK SEMICONDUCTOR CORPORATION, Hsinchu (TW)

(72) Inventor: Leaf CHEN, Kaohsiung City (TW)

(73) Assignee: REALTEK SEMICONDUCTOR CORPORATION, Hsinchu (TW)

(21) Appl. No.: 13/715,630

(22) Filed: Dec. 14, 2012

(30) Foreign Application Priority Data
Mar. 1, 2012 (TW) 101106728

(51) Int. Cl. G01R 19/165; G05F 1/10

(52) U.S. Cl. CPC G01R 19/16585; G05F 1/10
USPC 323/273; 324/612

(57) ABSTRACT

A modulating determination apparatus, a modulating determination method, and a power supply circuit thereof are provided. The modulating determination apparatus is electrically connected to an examined circuit and includes a driver circuit and a comparison circuit. The driver circuit provides an impulse signal to a first end of the examined circuit. The comparison circuit is coupled to the first end of the examined circuit to obtain a first detected electric value of the first end. The comparison circuit calculates a difference value between the first detected electric value and a second detected electric value. The comparison circuit produces a comparison result by comparing the difference value with a threshold value. The comparison result indicates whether the examined circuit comprises a passive component, which is used to decide either a first modulating scheme or a second modulating scheme for modulating the power supply circuit to supply an output power.

This application claims priority to Taiwan Patent Application No. 101106728 filed on Mar. 1, 2012.

### CROSS-REFERENCES TO RELATED APPLICATIONS

Not applicable.

### BACKGROUND OF THE INVENTION

1. Field of the Invention

The present invention relates to a modulating determination apparatus, a modulating determination method for use in a power supply circuit, and the power supply circuit. More particularly, the present invention relates to a power supply circuit having a plurality of modulating schemes, a modulating determination apparatus thereof, and a modulating determination method thereof.

2. Descriptions of the Related Art

Stable supply of electric power is an important factor for ensuring normal operations of various electronic circuits. In general electronic circuits, a regulator is disposed to supply a stable and reliable voltage level. However, different electronic circuits require different power supplies. In order to satisfy demands of different voltages in various electronic circuits, power supply integrated circuit (IC) manufacturers must design different kinds of regulators. For example, switching regulators and linear regulators are common ones, and among linear regulators, low dropout linear regulators have the simplest structures and are widely used.

Different regulators have to be coupled with different circuit components when being used. As an example, a switching regulator has to be coupled with an additional passive component (e.g., an inductor) when being used. In case no passive component is coupled in the circuit of the switching regulator or in case the passive component is broken due to factors such as dusts and moisture, the circuit becomes short-circuited. For this situation, a square-wave signal modulated by a switching circuit is presented directly at the output end, which cannot be used in the back-end circuits and may even damage components of the back-end circuits. As another example, when a low dropout linear regulator is used, no additional passive component is needed and, instead, it is connected in a short-circuited fashion for ensuring the voltage quality. If a passive component is coupled to the low dropout liner regulator, the low dropout linear regulator cannot operate efficiently.

Accordingly, there is an urgent need in the art to provide a technology that can detect a passive component conveniently to ensure normal operation of various electronic circuits (e.g., regulators).

### SUMMARY OF THE INVENTION

The present invention provides a modulating determination apparatus and a modulating determination method for use in a power supply circuit, and the power supply circuit.

The modulating determination apparatus is for use in a power supply circuit, is configured to be coupled to an examined circuit, and comprises a driver circuit and a comparison circuit. The examined circuit has a first end and a second end. The driver circuit provides an impulse signal to the first end. The comparison circuit is coupled to the first end to obtain a first detected electric value of the first end, calculates a difference value between the first detected electric value and a second detected electric value, and produces a comparison result by comparing the difference value with a threshold value. The comparison result indicates whether the examined circuit comprises a passive component, which is used to decide to modulate the power supply circuit by either a first modulating scheme or a second modulating scheme so as to supply an output power.

The modulating determination method is for use in a power supply circuit and comprises the following steps of: (a) providing an impulse signal to an end of an examined circuit; (b) detecting the end to obtain a first detected electric value; (c) obtaining a second detected electric value; (d) calculating a difference value between the first detected electric value and the second detected electric value; (e) producing a comparison result by comparing the difference value with a threshold value, the comparison result indicating whether the examined circuit comprises a passive component; and (f) modulating the power supply circuit by either a first modulating scheme or a second modulating scheme according to the comparison result so as to supply an output power.

The power supply circuit comprises a pin, a driver circuit, a comparison circuit, a switching regulator, a low dropout linear regulator, and a selection circuit. The pin is to be coupled to an examined circuit. The driver circuit is coupled to the pin and for providing an impulse signal to the examined circuit. The comparison circuit is coupled to the first pin to obtain a first detected electric value and for producing a comparison result according to a difference value between the first detected electric value and a second detected electric value. The selection circuit decides to supply an output power by either the switching regulator or the low dropout linear regulator according to the comparison result.

The present invention determines whether an examined circuit comprises a passive component by obtaining two detected electric values of two ends of the examined circuit and then comparing a difference value between the two detected electric values with a threshold value. Therefore, the present invention can efficiently detect whether an examined circuit comprises a desired passive component. When this technology is applied to a power supply circuit, the power supply circuit can determine whether a passive component is coupled by a user so as to activate a proper circuit or output a proper signal.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 illustrates the modulating determination apparatus of the first embodiment;

FIG. 2 illustrates the modulating determination apparatus of the second embodiment;

FIG. 3 illustrates the modulating determination method of the third embodiment;

FIG. 4 illustrates the power supply circuit of the fourth embodiment;

FIG. 5 illustrates the power supply circuit of the fifth embodiment;

FIG. 6 illustrates the power supply circuit of the sixth embodiment;

FIG. 7 illustrates the power supply circuit of the seventh embodiment;

FIG. 8 illustrates the power supply circuit of the eighth embodiment; and

FIG. 9 illustrates the power supply circuit of the ninth embodiment.

### DESCRIPTION OF THE PREFERRED EMBODIMENT

In the following description, the principle of the present invention will be described in detail. In addition, the modulating determination apparatus and the modulating determination method for use in a power supply circuit as well as the power supply circuit based on the present invention will be explained with reference to various embodiments. However, these embodiments are not intended to limit the present invention to any environment, applications, or implementations described in these embodiments. Therefore, description of these embodiments is only for purpose of illustration rather than to limit the present invention. It shall be appreciated that, in the following embodiments and the attached drawings, elements not directly related to the present invention are omitted from depiction.

The impedance of a passive component is related with the frequency of an input signal. For example, the impedance of an inductor is directly proportional to the frequency of an impulse signal inputted. Hence, the higher the frequency of the impulse signal is, the larger the potential difference across the inductor will be. Such a characteristic of the inductor may also be reflected by other detected electric values, e.g. current values.

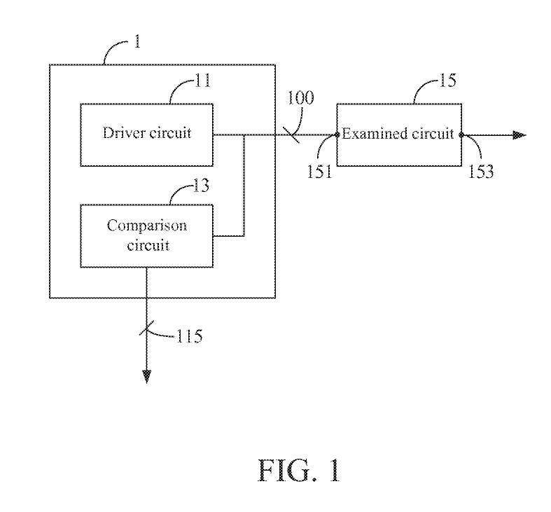

FIG. 1 depicts the first embodiment of the present invention. The modulating determination apparatus 1 comprises the driver circuit 11 and the comparison circuit 13, while the examined circuit 15 has the first end 151 and the second end 153. In this embodiment, the modulating determination apparatus 1 may be a power supply control integrated circuit (IC) and the examined circuit 15 may be any external circuit that needs to be connected with the power supply control IC to jointly output an appropriate power to back-end circuits. As shown in FIG. 1, the first end 151 of the examined circuit 15 is coupled to the driver circuit 11 and the comparison circuit 13, while the second end 153 is an output end which may be grounded or coupled to other electronic circuit components having a fixed detected electric value.

The driver circuit 11 provides the impulse signal 100 to the first end 151 of the examined circuit 15. Then, the comparison circuit 13 detects the first end 151 to obtain a first detected electric value and calculates a difference value between the first detected electric value and a second detected electric value of the second end 153. Since the output of the second end 153 is an expectable known value, the second detected electric value may be built in as a default value. Therefore, after detecting the first end 151, the comparison circuit 13 directly calculates the difference value between the first detected electric value and the built-in second detected electric value and then compares the difference value with a threshold value to output the comparison result 115. The comparison result 115 indicates whether the examined circuit 15 comprises a passive component. When the modulating determination apparatus 1 is used in a power supply circuit, modulating the power supply circuit by either a first modulating scheme or a second modulating scheme is decided according to whether a passive component exists so as to supply an output power.

In other embodiments, depending on the type and characteristics of the passive component and the type of the detected electric values, the comparison result 115 will present whether the examined circuit 15 comprises a passive component in different ways. For example, in case that the impedance of the passive component to be detected is positively correlated with the frequency of the impulse signal 100, the examined circuit 15 is determined to comprise the passive component if the comparison circuit learns that the difference value between the first detected electric value and the second detected electric value is greater than the threshold value. Continuing the same example, it is determined that the examined circuit 15 does to not comprise the passive component if the difference value between the first detected electric value and the second detected electric value is smaller than the threshold value.

The first detected electric value and the second detected electric value may be voltage values or current values. The passive component may be an inductor or a capacitor. In different embodiments, the present invention may be implemented by choosing different detected electric values according to the characteristics of the passive component to be measured.

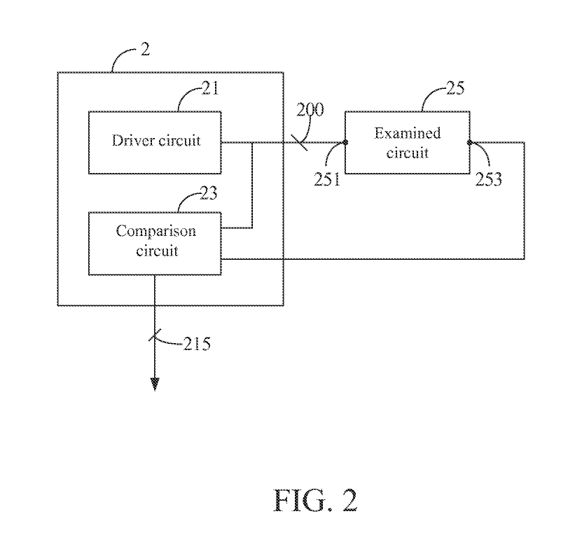

FIG. 2 depicts the second embodiment of the present invention. The modulating determination apparatus 2 comprises the driver circuit 21 and the comparison circuit 23, while the examined circuit 25 has the first end 251 and the second end 253. As the modulating determination apparatus 2 is similar to the modulating determination apparatus 1 of the first embodiment, only the differences therebetween are described below.

In the second embodiment, the comparison circuit 23 is coupled to not only the first end 251 but also the second end 253 of the examined circuit 25. Therefore, when the driver circuit 21 provides an impulse signal 200 to the first end 251, the comparison circuit 23 can directly detect and obtain a first detected electric value of the first end 251 and a second detected electric value of the second end 253. The difference value between the first detected electric value and the second detected electric value is compared with a threshold value by the comparison circuit 23 to output the comparison result 215. The comparison result 215 indicates whether the examined circuit 25 comprises a passive component.

In actual circuits, the output level of the second end 253 of the examined circuit 25 is expectable. Considering the example that the modulating determination apparatus 2 is a power supply control IC and the examined circuit 25 is an output inductor and they form a switching regulator (SWR) together. In this case, regardless of whether the second end 253 is coupled to the comparison circuit 23, the difference value between the first detected electric value and the second detected electric value can be predicted through some techniques so as to determine the threshold value. In practical implementations, the input end for inputting the second detected electric value of the comparison circuit 23 may be designed to be grounded or directly coupled to some other node having a fixed voltage. In a preferred embodiment, the second detected electric value is a nonzero default value. As long as the difference value between the first detected electric value and the second detected electric value can exhibit the electric characteristic of the examined circuit 25 adequately and the threshold value is appropriately set, whether the examined circuit 25 comprises a passive component can be effectively determined It shall be noted that, if the comparison result 215 indicates that the examined circuit 25 has no inductive characteristic, it represents that the current circuit cannot be provided with a power by an SWR control approach. In this case, the output of the power supply must be turned off; or instead, the power is outputted by some other control approach that does not require existence of an inductor (e.g., the output is supplied to the second end 253 by a control approach using a low dropout linear regulator instead).

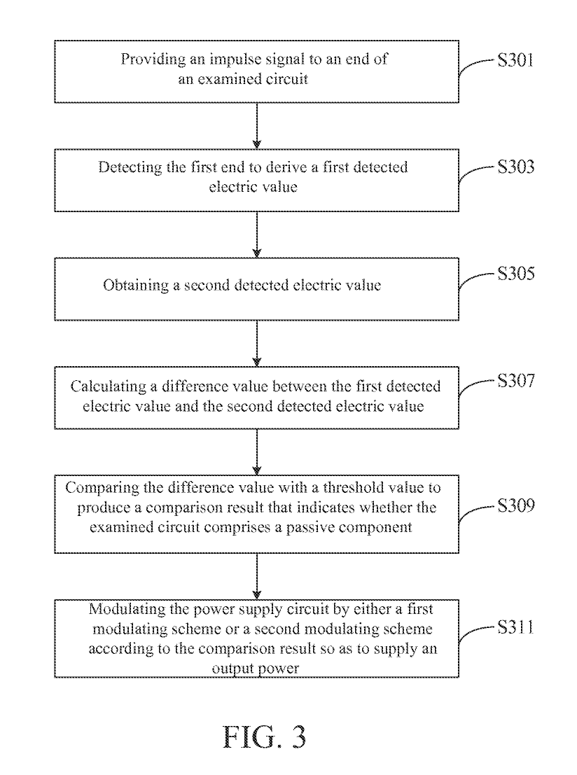

The third embodiment of the present invention is a modulating determination method, a flowchart diagram of which is depicted in FIG. 3. This modulating determination method can be applied to a power supply circuit. Hardware architectures that can realize this modulating determination method can refer to the modulating determination apparatus 1 or the modulating determination apparatus 2 described above.

Firstly, step S301 is executed to provide an impulse signal to an end of an examined circuit. Next, step S303 is executed to detect the end of the examined circuit to obtain a first detected electric value. Then, step S305 is executed to obtain a second detected electric value. It shall be appreciated that, in other embodiments, step S305 may be executed before step S303 or steps S303 and S305 may be executed simultaneously.

Then, step S307 is executed to calculate a difference value between the first detected electric value and the second detected electric value. Step S309 is executed to compare the difference value with a threshold value to produce a comparison result, which indicates whether the examined circuit comprises a passive component. Finally, step S311 is executed to modulate the power supply circuit by either a first modulating scheme or a second modulating scheme according to the comparison result so as to supply an output power.

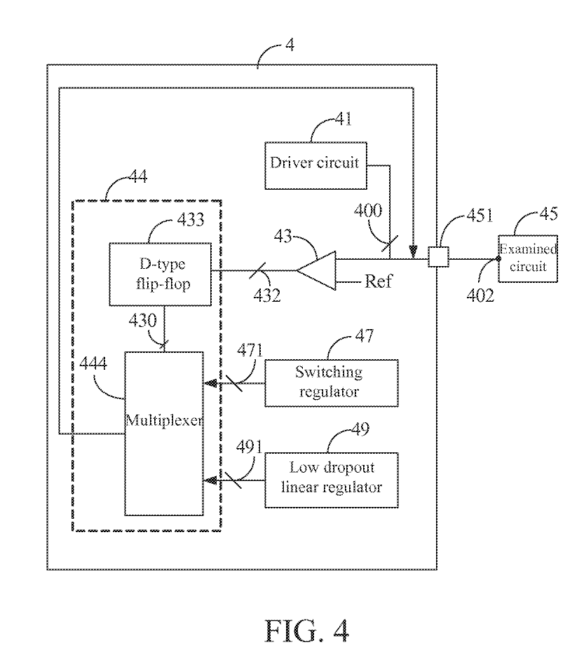

FIG. 4 depicts the fourth embodiment of the present invention. The power supply circuit 4 comprises the pin 451, the driver circuit 41, the comparison circuit 43, the switching regulator 47, the low dropout linear regulator 49, and the selection circuit 44. The selection circuit 44 comprises the D-type flip-flop 433 and the multiplexer 444.

In this embodiment, the driver circuit 41 may be a p-channel metal-oxide-semiconductor field-effect transistor (PMOSFET). Additionally, the driver circuit 41, the comparison circuit 43, the switching regulator 47, the low dropout linear regulator 49, the D-type flip-flop 433, and the multiplexer 444 are all well known by those of ordinary skill in the art, and thus will not be further described herein.

As shown, when the end 402 of the examined circuit 45 is coupled to the pin 451, the driver circuit 41 provides the impulse signal 400 to the examined circuit 45 via the pin 451. The comparison circuit 43 also detects and obtains a first detected electric value of the end 402 via the pin 451, calculates a difference value between the first detected electric value and the second detected electric value Ref, and produces the comparison result 432 according to the difference value (e.g., by comparing the difference value with a threshold value).

The selection circuit 44 decides to supply an output power by either the switching regulator 47 or the low dropout linear regulator 49 according to the comparison result 432.

Specifically, the D-type flip-flop 433 is coupled to the comparison circuit 43, receives the comparison result 432 from the comparison circuit 43, and outputs the control signal 430 according to the comparison result 432. The multiplexer 444 is coupled to the switching regulator 47, the low dropout linear regulator 49, and the D-type flip-flop 433. According to the control signal 430, the first output signal 471 generated by the switching regulator 47 or the second output signal 491 generated by the low dropout linear regulator 49 is outputted by the multiplexer 444 to the pin 451 as the output power for output to the examined circuit 45.

When the power supply circuit 4 starts to provide the output power to the examined circuit 45, the driver circuit 41 stops providing the impulse signal 400 to the examined circuit 45. In other embodiments, the driver circuit 41 may be activated when connection of the examined circuit is detected (hot plugging detection) and then turned off after a preset time period, or may execute other commands from the system.

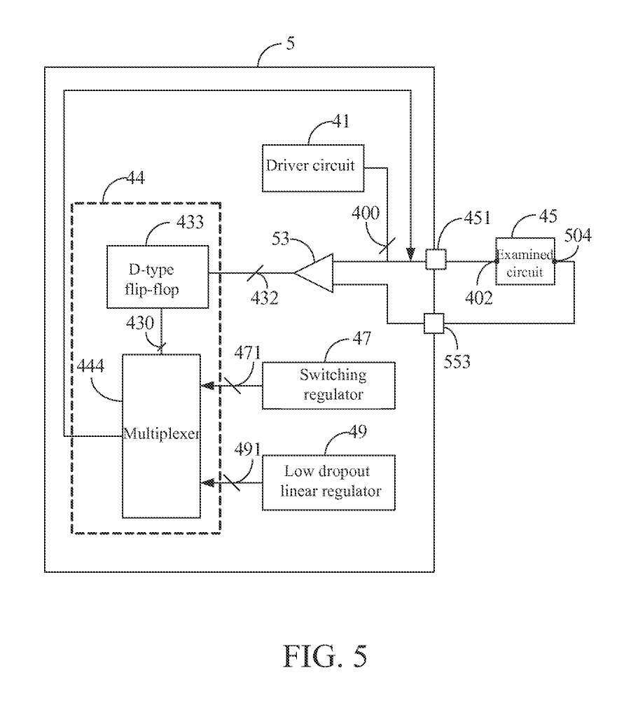

FIG. 5 depicts the fifth embodiment of the present invention. The power supply circuit 5 of this embodiment is similar to the power supply circuit 4 of the fourth embodiment, so only the differences therebetween are focused below. In this embodiment, the end 402 and the end 504 of the examined circuit 45 are coupled to the pin 451 and the pin 553 of the power supply circuit 5 respectively. Therefore, the comparison circuit 53 not only obtains the first detected electric value via the pin 451 but also obtains the second detected electric value via the pin 553. Then, the comparison circuit 53 calculates the difference value between the first detected electric value and the second detected electric value and outputs the comparison result 432 by comparing the difference value with a threshold value. Afterwards, since the comparison result 432 indicates whether a passive component exists or not, the D-type flip-flop 433 and the multiplexer 444 choose to operate in different ways accordingly so that the first output signal 471 generated by the switching regulator 47 or the second output signal 491 generated by the low dropout linear regulator 49 is outputted to the pin 451 as the output power for output to the examined circuit 45.

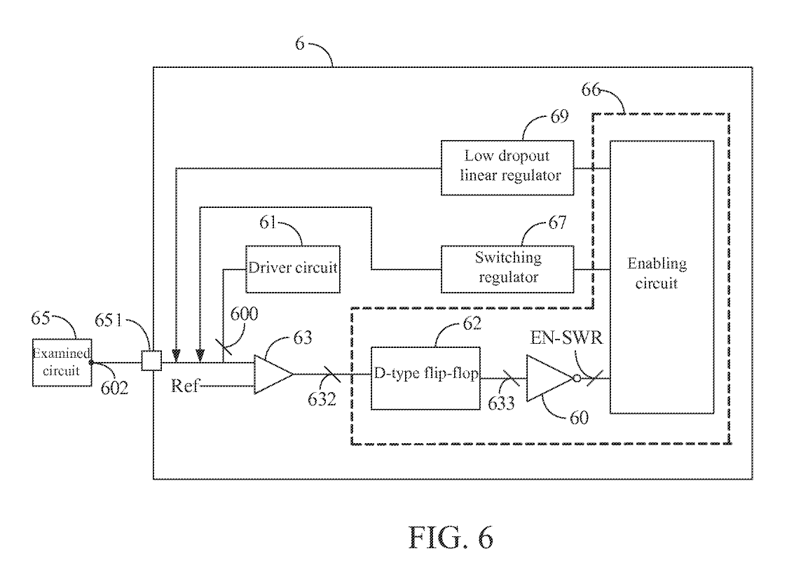

FIG. 6 depicts the sixth embodiment of the present invention. The power supply circuit 6 comprises the pin 651, the driver circuit 61, the comparison circuit 63, the switching regulator 67, the low dropout linear regulator 69, and the selection circuit 66. The selection circuit 66 comprises the D-type flip-flop 62, the inverter 60, and the enabling circuit 64.

The end 602 of the examined circuit 65 is coupled to the power supply circuit 6 via the pin 651. In this embodiment, the driver circuit 61 may be a PMOSFET. The driver circuit 61 provides the impulse signal 600 to the pin 651. The comparison circuit 63 is coupled to the pin 651, obtains a first detected electric value from the pin 651, calculates a difference value between the first detected electric value and a preset second detected electric value Ref, and produces the comparison result 632 according to the difference value.

The selection circuit 66 decides to supply an output power by either the switching regulator 67 or the low dropout linear regulator 69 according to the comparison result 632. Specifically, the D-type flip-flop 62 is coupled to the comparison circuit 63 and outputs a control signal 633 according to the comparison result 632. The input end of the inverter 60 is coupled to the D-type flip-flop 62 and the inverter 60 generates an inverted signal EN-SWR according to the control signal 633. The enabling circuit 64 is coupled to the switching regulator 67, the low dropout linear regulator 69, and the inverter 60, receives the inverted signal EN-SWR from the inverter 60, and enables either the switching regulator 67 or the low dropout linear regulator 69 according to the inverted signal EN-SWR. The switching regulator 67 or the low dropout linear regulator 69 that is enabled then supplies the output power to the examined circuit 65 via the pin 651.

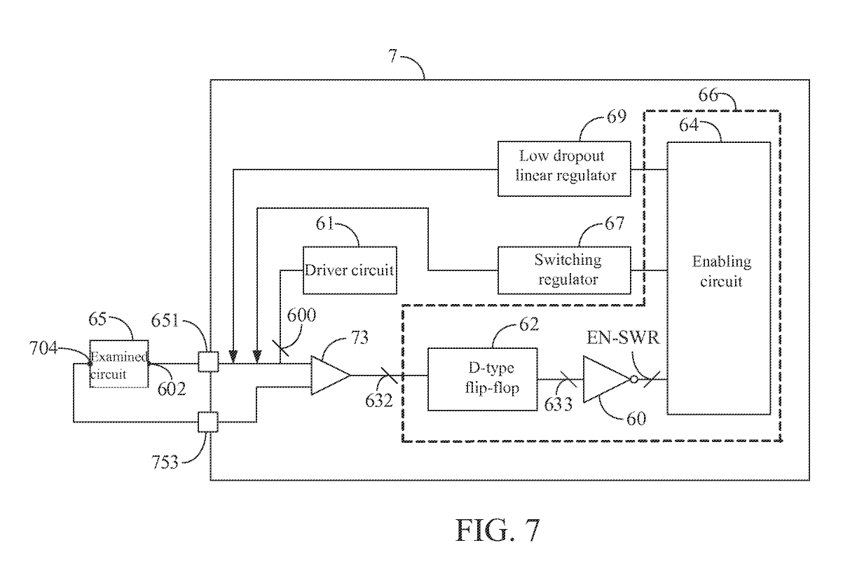

FIG. 7 depicts the seventh embodiment of the present invention. The end 602 and the end 704 of the examined circuit 65 are coupled to the pin 651 and the pin 753 of the power supply circuit 7 respectively. The comparison circuit 73 receives a first detected electric value via the first pin 651 and also receives a second detected electric value via the second pin 753. The comparison circuit 73 then calculates the difference value between the first detected electric value and the second detected electric value and outputs the comparison result 632 by comparing the difference value with a threshold value.

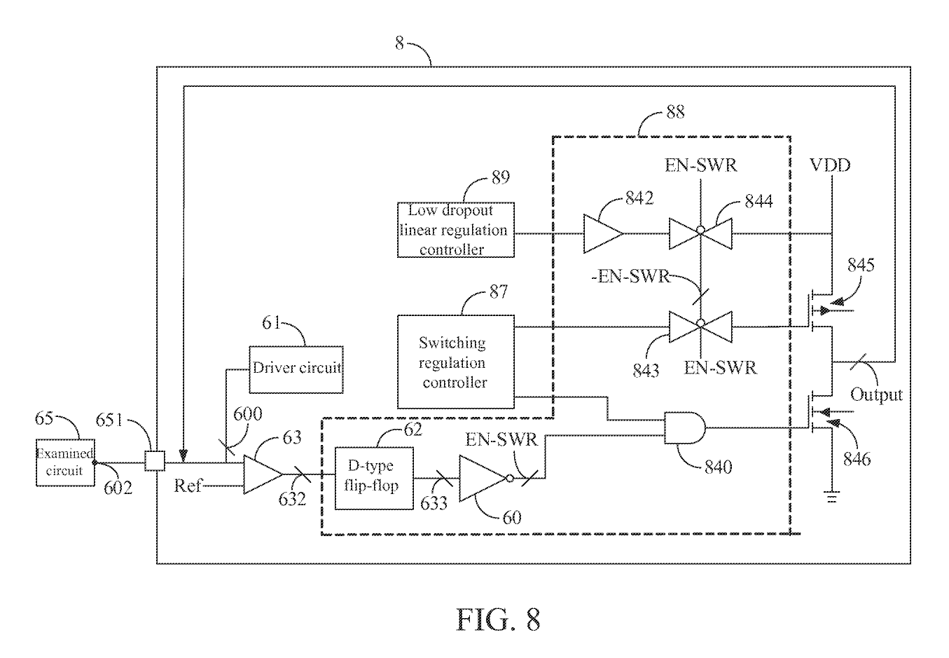

FIG. 8 depicts the eighth embodiment of the present invention. Similar to the power supply circuit 6 of the sixth embodiment, the power supply circuit 8 also comprises the pin 651, the driver circuit 61, and the comparison circuit 63. The couplings and operations of these components are the same as those of the components of the power supply circuit 6 of the sixth embodiment, and thus will not be further described herein.

The power supply circuit 8 further comprises the selection circuit 88, the PMOSFET 845, the N-channel metal-oxide-semiconductor field-effect transistor (NMOSFET) 846, the switching regulation controller 87, and the low dropout linear regulation controller 89. The PMOSFET 845, the NMOSFET 846, and the switching regulation controller 87 can form a switching regulator; while the PMOSFET 845, the NMOSFET 846, and the low dropout linear regulation controller 89 can form a low dropout linear regulator. In other words, the switching regulator and the low dropout linear regulator of this embodiment have a common power stage.

The selection circuit 88 comprises the D-type flip-flop 62, the inverter 60, the AND gate 840, the error amplifier 842, and the transmission gates 843 and 844. The PMOSFET 845 has a source being coupled to a power supply (VDD) and a drain being coupled to a source of the NMOSFET 846. The drain of the NMOSFET 846 is grounded.

The first input end of the AND gate 840 receives the inverted signal EN-SWR, the second input end of the AND gate 840 is coupled to the switching regulation controller 87, and the output end of the AND gate 840 is coupled to the gate of the NMOSFET 846. The transmission gates 843 and 844 are coupled to each other. The first end of the transmission gate 843 is coupled to the switching regulation controller 87 and the second end of the transmission gate 843 is coupled to a gate of the PMOSFET 845. The transmission gates 843 and 844 have a negative inverted signal −EN-SWR therebetween. The error amplifier 842 has the input end coupled to the low dropout linear regulation controller 89 and the output end coupled to the first end of the transmission gate 844. The second end of the transmission gate 844 is coupled to the source of the PMOSFET 845.

When the inverted signal EN-SWR is at a high level, the output of the switching regulation controller 87 passes through the AND gate to turn on the NMOSFET 846. Furthermore, another output of the switching regulation controller 87 passes through the transmission gate 843 to turn on the PMOSFET 845. In this case, the switching regulation controller 87 generates the output signal Output as the output power for outputting to the examined circuit 65. It is learned that when the inverted signal EN-SWR is at the high level, the switching regulator formed by the PMOSFET 845, the NMOSFET 846, and the switching regulation controller 87 is activated.

When the inverted signal EN-SWR is at a low level, the output of the switching regulation controller 87 is unable to pass through the AND gate 840. Instead, the output of the low dropout linear regulation controller 89 controls the PMOSFET 845 and the NMOSFET 846. In this case, the low dropout linear regulation controller 89 generates an output signal Output as an output power for outputting to the examined circuit 65. It is learned that when the inverted signal EN-SWR is at the low level, the low dropout linear regulator formed by the PMOSFET 845, the NMOSFET 846, and the low dropout linear regulation controller 89 is activated.

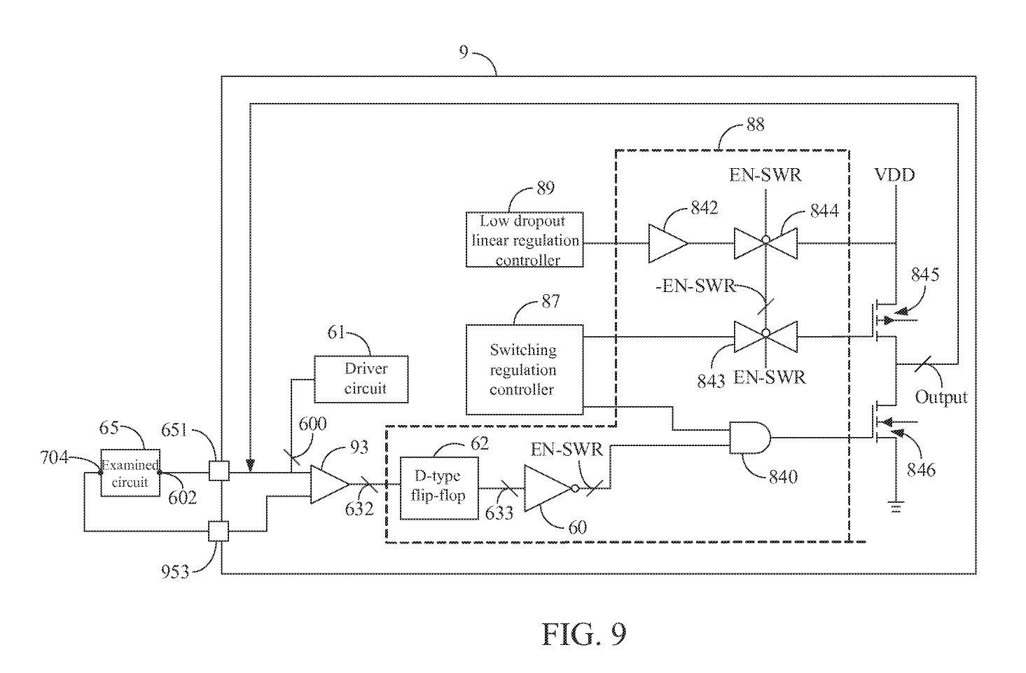

FIG. 9 depicts the ninth embodiment of the present invention. In this embodiment, the comparison circuit 93 not only obtains a first detected electric value via a pin 651 but also obtains a second detected electric value via a pin 953 so as to produce the comparison result 632.

According to the above embodiments, by virtue of the correlation between the impedance of a passive component and the frequency of an impulse signal, the present invention calculates a difference value between detected electric values of two ends of an examined circuit and then compares the difference value with a threshold value to produce a comparison result which indicates whether the examined circuit comprises a passive component. This technical feature can be further applied to a power supply circuit and implemented by various circuits. In this way, abnormal operations, short circuits, or burnout of the circuit can be avoided.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A modulating determination apparatus for use in a power supply circuit, being configured to be coupled to an examined circuit, the modulating determination apparatus comprising:
a driver circuit for providing an impulse signal to a first end of the examined circuit; and
a comparison circuit, coupled to the first end of the examined circuit to obtain a first detected electric value, calculating a difference value between the first detected electric value and a second detected electric value, and producing a comparison result by comparing the difference value with a threshold value,
wherein the comparison result indicates whether the examined circuit comprises a passive component, which is used to decide to modulate the power supply circuit by either a first modulating scheme or a second modulating scheme so as to supply an output power.

2. The modulating determination apparatus of claim 1, wherein the comparison result indicates that the examined circuit comprises the passive component when the difference value is greater than the threshold value.

3. The modulating determination apparatus of claim 1, wherein the comparison result indicates that the examined circuit does not comprise the passive component when the difference value is smaller than the threshold value.

4. The modulating determination apparatus of claim 1, wherein the first detected electric value and the second detected electric value are voltage values.

5. The modulating determination apparatus of claim 1, wherein the first detected electric value and the second detected electric value are current values.

6. The modulating determination apparatus of claim 1, wherein the comparison circuit is further coupled to the second end of the examined circuit and the second detected electric value is obtained from the second end.

7. The modulating determination apparatus of claim 1, wherein the passive component is one of an inductor and a capacitor.

8. The modulating determination apparatus of claim 1, wherein the second detected electric value is a built-in default value.

9. A modulating determination method for use in a power supply circuit, comprising the following steps of:
providing an impulse signal to a first end of an examined circuit;
detecting the first end to obtain a first detected electric value;
obtaining a second detected electric value;
calculating a difference value between the first detected electric value and the second detected electric value;
producing a comparison result by comparing the difference value with a threshold value, the comparison result indicating whether the examined circuit comprises a passive component; and
modulating the power supply circuit by either a first modulating scheme or a second modulating scheme according to the comparison result so as to supply an output power.

10. The modulating determination method of claim 9, wherein the comparison result indicates that the examined circuit comprises the passive component when the difference value is greater than the threshold value.

11. The modulating determination method of claim 9, wherein the comparison result indicates that the examined circuit does not comprise the passive component when the difference value is smaller than the threshold value.

12. The modulating determination method of claim 9, wherein the first detected electric value and the second detected electric value are voltage values.

13. The modulating determination method of claim 9, wherein the first detected electric value and the second detected electric value are current values.

14. The modulating determination method of claim 9, wherein the second detected electric value is obtained from a second end of the examined circuit.

15. The modulating determination method of claim 9, wherein the passive component is one of an inductor and a capacitor.

16. A power supply circuit, comprising:
a first pin to be coupled to an examined circuit;
a driver circuit, being coupled to the first pin and for providing an impulse signal to the examined circuit;
a comparison circuit, being coupled to the first pin to obtain a first detected electric value and for producing a comparison result according to a difference value between the first detected electric value and a second detected electric value;
a switching regulator;
a low dropout linear regulator; and
a selection circuit, for deciding to supply an output power by either the switching regulator or the low dropout linear regulator according to the comparison result.

17. The power supply circuit of claim 16, wherein the selection circuit comprises:
a D-type flip-flop, being coupled to the comparison circuit and for outputting a control signal according to the comparison result; and
a multiplexer, being coupled to the switching regulator, the low dropout linear regulator, and the D-type flip-flop and for setting either an output of the switching regulator or an output of the low dropout linear regulator as the output power according to the control signal.

18. The power supply circuit of claim 16, wherein the selection circuit enables either the switching regulator or the low dropout linear regulator according to the comparison result so as to supply the output power.

19. The power supply circuit of claim 16, wherein the switching regulator and the low dropout linear regulator have a common power stage.

20. The power supply circuit of claim 16, wherein the selection circuit comprises:
a D-type flip-flop, being coupled to the comparison circuit and for outputting a control signal according to the comparison result;
an inverter, being coupled to the D-type flip-flop and for outputting an inverted signal of the control signal; and
an enabling circuit, being coupled to the switching regulator, the low dropout linear regulator, and the inverter, for receiving the inverted signal from the inverter, and for enabling either the switching regulator or the low dropout linear regulator according to the inverted signal so as to supply the output power.

21. The power supply circuit of claim 16, wherein the first detected electric value and the second detected electric value are voltage values.

22. The power supply circuit of claim 16, wherein the first detected electric value and the second detected electric value are current values.

23. The power supply circuit of claim 16, further comprising:
a second pin,
wherein the comparison circuit is further coupled to the second pin and obtains the second detected electric value from the second pin.
